(19) United States
(12) Patent Application Publication
(10) Pub. No.: US 2016/0069508 A1
(43) Pub. Date: Mar. 10, 2016

(54) MOBILE DEVICE STAND

(71) Applicant: American Covers, Inc., Draper, UT (US)

(72) Inventors: Bryce Haymond, Draper, UT (US); Jason Fogg, Lake Point, UT (US)

(21) Appl. No.: 14/479,574

(22) Filed: Sep. 8, 2014

(51) Int. Cl. F16M 11/38; H05K 5/00; H05K 5/02

(52) U.S. Cl. CPC F16M 11/38; H05K 5/0204; H05K 5/0086

(57) ABSTRACT

A mobile device stand comprises a substantially rigid sheet having both an initial unfolded configuration patterned with slots and fold lines to define a perimeter base, an interior backrest and a shelf, and a subsequent folded configuration with the sheet folded at the fold lines to define the stand.

### BACKGROUND

1. Field of the Invention

The present invention relates generally to a mobile device stand for cellular phones, smart phones, tablet computers, and the like. More particularly, the present invention relates to a stand patterned and folded into shape from a planar sheet into a three-dimensional stand.

2. Related Art

Mobile devices are often coupled to computers and disposed on desks while charging or updating software or downloading/uploading data. The mobile device can be difficult to view when resting on the desk.

### SUMMARY OF THE INVENTION

It has been recognized that it would be advantageous to develop an apparatus or method for supporting a mobile device in an upright or inclined orientation to facilitate viewing.

The invention provides a mobile device stand comprising a substantially rigid sheet having both an initial unfolded configuration with slots defining portions and fold lines, and a subsequent folded configuration with the sheet folded at the fold lines and the portions being displaced from the flat configuration to define the stand. A perimeter base portion extends around a perimeter of the rigid sheet in the initial unfolded configuration. An interior backrest portion is circumscribed by the perimeter base portion in the initial unfolded configuration, and is separated from the perimeter base portion by a first slot extending around a majority of the interior backrest portion, and is attached to the perimeter base portion by a first fold line. A shelf portion is circumscribed by the interior backrest portion in the initial unfolded configuration, and is separated from the interior backrest portion by a second slot extending around a majority of the shelf portion, and is attached so the interior backrest portion by a second fold line. The interior backrest portion is folded about the first fold line at an acute angle with respect to the perimeter base portion in the subsequent folded configuration. The shelf portion is folded about the second fold line at substantially a right angle with respect to the interior backrest portion in the subsequent folded configuration. The second fold line and the second slot are configured to locate the shelf adjacent a support surface and the first fold line.

In addition, the invention provides a mobile device stand comprising a substantially rigid sheet having both an initial unfolded configuration patterned with slots and fold lines to define a perimeter base, an interior backrest and a shelf, and a subsequent folded configuration with the sheet folded at the fold lines to define the stand. A first slot and a first fold line are in the sheet and together surround and define the interior backrest in the sheet and within the perimeter base in the initial unfolded configuration. A second slot and a second fold line are in the sheet and together surround and define the shelf in the sheet and within the interior backrest in the initial unfolded configuration. The interior backrest and the shelf each have a proximal attachment end at the first and second fold lines, respectively, with the proximal attachment ends and the first and second fold lines being proximal one another, and closer to a front of the stand in the subsequent folded configuration than an opposite rear of the stand.

### BRIEF DESCRIPTION OF THE DRAWINGS

Additional features and advantages of the invention will be apparent from the detailed description which follows, taken in conjunction with the accompanying drawings, which together illustrate, by way of example, features of the invention; and, wherein:

FIG. 1 is a perspective view of a mobile device stand in accordance with an embodiment of the present invention, shown in a subsequent folded configuration;

FIG. 2 is a perspective view of the mobile device stand of FIG. 1, shown in the subsequent folded configuration and with a mobile device disposed thereon;

FIG. 3 is a top view of the mobile device stand of FIG. 1, shown in an initial unfolded configuration.

Reference will now be made to the exemplary embodiments illustrated, and specific language will be used herein to describe the same. It will nevertheless be understood that no limitation of the scope of the invention is thereby intended.

### DETAILED DESCRIPTION OF EXAMPLE EMBODIMENT(S)

### Definitions

The term “mobile device” is used broadly herein to refer to a portable, hand-held electronic device, including by way of example, a cellular (cell) phone, a smart phone, a tablet computer or tablet, a global positioning system (GPS), a mobile media player, a gaming system, and the like. Such a device can have a display screen upon which data, information, media, etc. is viewed; one or more inputs, such as buttons, a touch screen, etc.; one or more outputs, such as the screen, a speaker, an audio jack, etc.; a power supply, such as a battery; a data storage system and a computing system. Such a device can also include a port or socket for receiving a power and/or data connection cord or plug.

The terms “business”, “company” are used broadly and interchangeably herein to refer to an organization that provides a product or a service. The business, company or organization can have a name, logo, slogan, trademark, service mark, etc. that is capable of identifying and/or distinguishing the business or company, or product or service, or both, or can otherwise be utilized to market, promote, and/or brand the business or company, or product or service, or both.

### Description

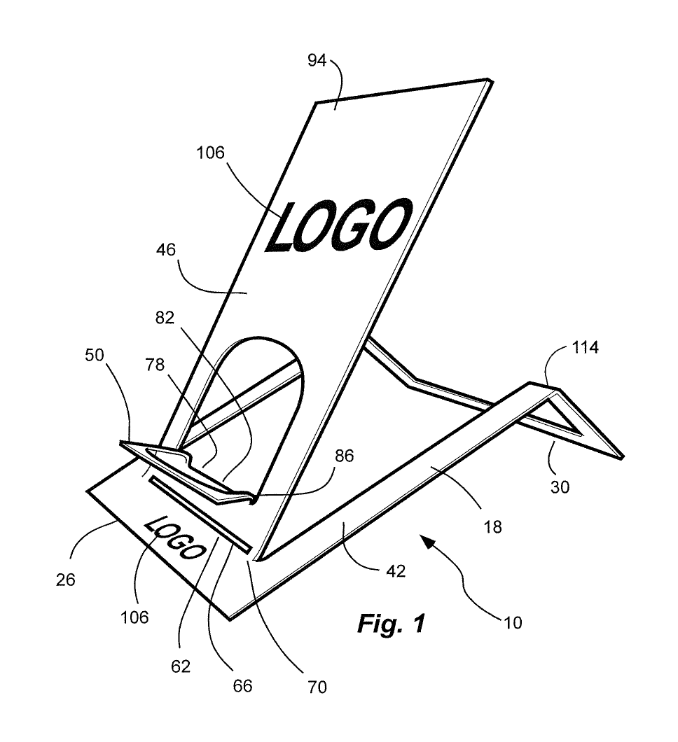

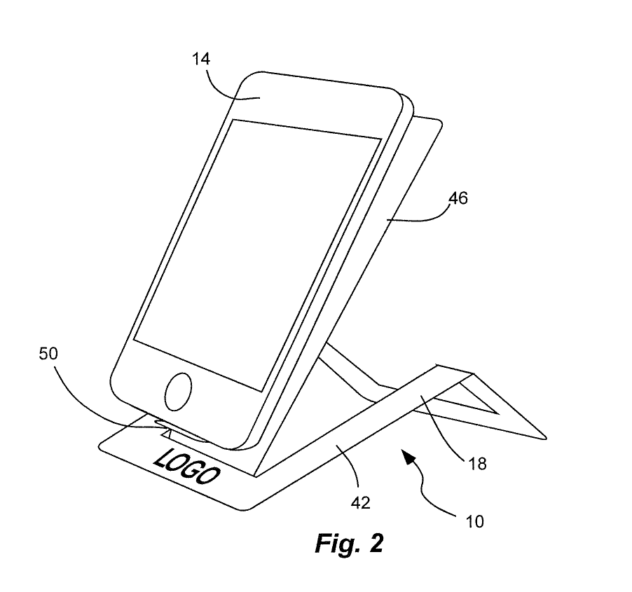

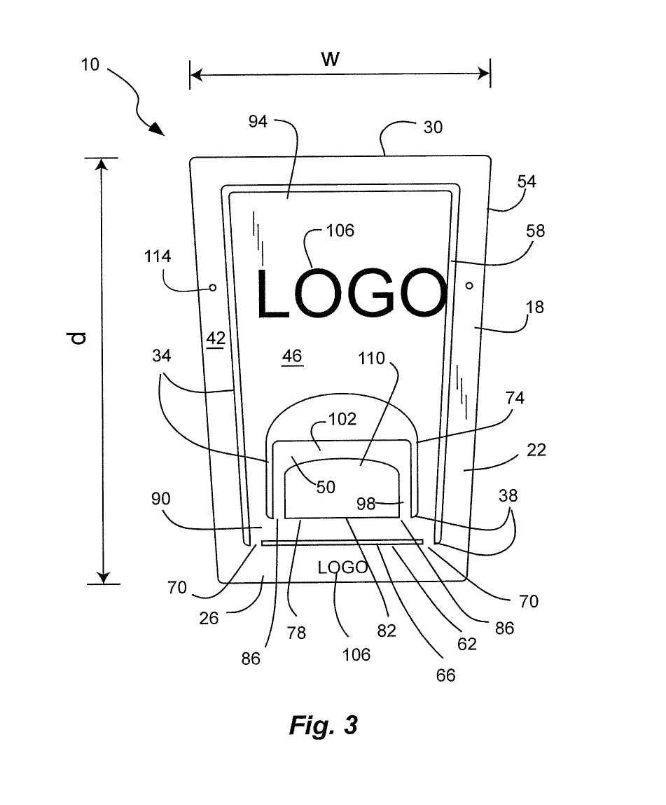

As illustrated in FIGS. 1-3, a mobile device stand, indicated generally at 10, or a stand device configured for use with a mobile device 14, in an example implementation in accordance with the invention is shown with the mobile device thereon. The stand 10 can have an initial unfolded configuration (FIG. 3), and a subsequent folded configuration (FIGS. 1 and 2). In the initial unfolded configuration, the stand or sheet thereof can be substantially flat. Thus, the stand can be provided in the initial folded configuration for transportation and/or shipping to reduce shipping costs, and to provide distribution convenience. In the subsequent folded configuration, the stand or sheet thereof can be bent or folded about fold lines and/or slots (defining living hinges) to define the stand, which can be disposed on a support surface, such as a desk or shelf, and can receive the mobile device thereon. Thus, the stand can support and hold the mobile device for convenient viewing and/or charging. In addition, the stand can have indicia indicative of or representing a business, a product, or both, thereon. Thus, the stand can be used as a promotional device.

The stand 10 can comprise a substantially rigid sheet 18 (FIG. 3). The sheet 18 can be sufficiently rigid to sustain its shape absent an applied force, but capable of being bent under a manual force applied by hand. In one aspect, the sheet 18 can be or can comprise a sheet of metal, such as stainless steel. The sheet can have a front or top or outer surface 22, and an opposite rear surface. In addition, the sheet can have opposite front and rear ends 26 and 30. In one aspect, the sheet can have a coating or clear coat on at least the front surface 22. The coating can resist fingerprints and the like. In one aspect, the sheet can comprise a single sheet. The sheet can have a thickness of between 0.5-2 mm, in one aspect.

The stand 10 and the sheet 18 can have both an initial unfolded configuration (FIG. 3), and a subsequent folded configuration (FIGS. 1 and 2). In one aspect, the stand and the sheet can be substantially flat in the initial unfolded configuration. The stand and the sheet can have the same thickness as the thickness of the sheet in the initial unfolded configuration.

In addition, the sheet can have slots 34 and fold lines 38 therein that define separate and/or discrete portions in the sheet. The slots can extend through the sheet. The fold lines can comprise slots, holes, perforations, score lines, etc., or combinations thereof. The slots and the sheet or perimeter thereof can be formed by stamping the sheet. In the subsequent folded configuration, the sheet 18 is folded at the fold lines, and the portions are displaced from the flat configuration to define the stand.

The slots and fold lines can define a perimeter base or perimeter base portion 42, an interior backrest or interior backrest portion 46, and a shelf or shelf portion 50. The perimeter base portion 42 can extend around a perimeter 54 of the sheet in the initial unfolded configuration. A first slot 58 and a first fold line 62 can be formed in the sheet, and can together surround and define the interior backrest portion 46 in the sheet, and within the perimeter base portion 42 in the initial unfolded configuration. The interior backrest portion 46 can be circumscribed by the perimeter base portion 42 in the initial unfolded configuration. The interior backrest portion 46 can be separated from the perimeter base portion 42 by the first slot 58 which can extend around a majority of the interior backrest portion, and can be attached to the perimeter base portion by the first fold line 62. In one aspect, the first slot 58 can have a U-shape. The first fold line 62 can comprise a third slot 66 extending between, but spaced-apart from, opposite ends of the first slot, and across an opening of the U-shape. The perimeter base portion 42 can be defined between the first and third slots 58 and 66, and the perimeter 54 of the sheet. The interior backrest portion 46 can be movably coupled to the perimeter base portion 42 by a first pair of connectors 70. The connectors 70 can be integral with the sheet, and can be formed and defined between the third slot 66 and the opposite ends of the first slot 58. The first pair of connectors 70 can define living hinges about which the interior backrest portion bends or folds with respect to the perimeter base portion 42. Thus, the first fold line 62 can comprise the first pair of connectors 70 and the third slot 66.

The shelf portion 50 can be circumscribed by the interior backrest portion 46 in the initial unfolded configuration. A second slot 74 and a second fold line 78 can be formed in the sheet, and can together surround and defining the shelf portion 50 in the sheet, and within the interior backrest portion 46 in the initial unfolded configuration. The shelf portion 50 can be separated from the interior backrest portion 46 by the second slot 74 extending around a majority of the shelf portion, and can be attached to the interior backrest portion by the second fold line 78. In one aspect, the second slot 74 can have a U-shape. The second fold line 78 can comprise a fourth slot 82 extending between, but spaced-apart from, opposite ends of the second slot 74, and across an opening the of the U-shape of the second slot. The interior backrest portion 46 can be defined between the second and fourth slots 74 and 82, and the perimeter base portion 42. The shelf portion 50 can be movably coupled to the interior backrest portion 46 by a second pair of connectors 86. The connectors 86 can be integral with the sheet, and can be formed and defined between the fourth slot 82 and the opposite ends of the second slot 74. The second pair of connectors 86 can defining living hinges about which the shelf portion bends of folds with respect to the interior backrest portion. The second fold line 78 can comprise the second pair of connectors 86 and the fourth slot 82.

The interior backrest portion 46 can have a proximal attachment end 90 attached to the sheet and the perimeter base portion 42. The interior backrest portion 46 can have an opposite distal free end 94. Similarly, the shelf portion 50 can have a proximal attachment end 98 attached to the sheet and the interior backrest portion 46. The shelf portion 50 can have an opposite distal free end 102.

In the subsequent folded configuration, the interior backrest portion 46 can be folded about the first fold line 62 at an acute angle with respect to the perimeter base portion 42. In addition, the shelf portion 50 can be folded about the second fold line 78 at substantially a right angle with respect to the interior backrest portion 46. The second fold line 78 and the second slot 74 can be configured to locate the shelf portion 50 adjacent or proximal to a support surface upon which the stand is disposed, and thus adjacent or proximal the first fold line 62. The interior backrest and the shelf can have the proximal attachment ends 90 and 98 at the first and second fold lines 62 and 78, respectively. The proximal attachment ends and the first and second fold lines can be adjacent or proximal one another, and closer to the front 26 of the stand in the subsequent folded configuration than the opposite rear 30 of the stand.

The stand can have a profile with the perimeter base portion 42, the interior backrest portion 46 and the shelf portion 50 radiating from proximal attachment ends 90 and 98 attached to one another at or near the front end 26, to distal free ends 94 and 102. The stand and the sheet can have indicia 106 indicative of or representing a business, a product, or both. The indicia can be disposed on an outward facing surface 22 of the interior backrest portion 46, the perimeter base portion 42, or both. The indicia can be laser etched, screen printed, sublimation printed, an adhesive layer, etc.

In addition, the shelf or shelf portion 50 can have a hole 110 between lateral sides of the shelf portion. The hole can receive a charging and/or data cord of the handheld device when on the shelf The shelf can be elevated above the perimeter base portion 42, and thus the support surface, in the subsequent folded configuration to accommodate the cord.

Furthermore, the stand, the sheet or the perimeter base portion can have a fifth fold line 114 closer to the rear end 30. The perimeter base portion can fold about the fifth fold line to form an obtuse angle, and to position the front and rear ends on the support surface, with the remaining portion of the perimeter base portion elevated from the support surface.

The stand can be sized for the mobile device. In one aspect, the sheet 18 can have a depth d between 80 and 120 mm, and a width w between 60 and 90 mm; or a depth d between 100 and 105 mm, and a width between 70 and 75 mm, for a smart phone. In another aspect, the sheet 18 can have a depth d between 140 and 180 mm, and a width w between 80 and 120 mm; or a depth d between 160 and 170 mm, and a width between 100 and 110 mm, for a tablet.

A method for providing the stand described above, and supporting the handheld device, comprises: transporting the sheet 18 in the initial unfolded configuration; folding the sheet about the first and second fold lines 62 and 78 to form the stand; disposing the stand on the support surface; and removably disposing a mobile device 14 on the shelf portion 50 of the stand, and leaning the mobile device against the interior backrest portion 46 of the stand. The sheet can be easily and inexpensively transported either alone or in bulk the initial unfolded configuration. In addition, the method can further comprise: passing a cord through a hole 110 between lateral sides of the shelf portion; and removably coupling a plug of the cord into a socket of the mobile device.

While the forgoing examples are illustrative of the principles of the present invention in one or more particular applications, it will be apparent to those of ordinary skill in the art that numerous modifications in form, usage and details of implementation can be made without the exercise of inventive faculty, and without departing from the principles and concepts of the invention. Accordingly, it is not intended that the invention be limited, except as by the claims set forth below.

1. A mobile device stand, comprising:
a) a substantially rigid sheet having both an initial unfolded configuration with slots defining portions and fold lines, and a subsequent folded configuration with the sheet folded at the fold lines and the portions being displaced from the flat configuration to define the stand;
b) a perimeter base portion extending around a perimeter of the rigid sheet in the initial unfolded configuration;
c) an interior backrest portion circumscribed by the perimeter base portion in the initial unfolded configuration, and separated from the perimeter base portion by a first slot extending around a majority of the interior backrest portion, and attached to the perimeter base portion by a first fold line;
d) a shelf portion circumscribed by the interior backrest portion in the initial unfolded configuration, and separated from the interior backrest portion by a second slot extending around a majority of the shelf portion, and attached so the interior backrest portion by a second fold line;
e) the interior backrest portion being folded about the first fold line at an acute angle with respect to the perimeter base portion in the subsequent folded configuration;
f) the shelf portion being folded about the second fold line at substantially a right angle with respect to the interior backrest portion in the subsequent folded configuration; and
g) the second fold line and the second slot being configured to locate the shelf adjacent a support surface and the first fold line.

2. The stand in accordance with claim 1, further comprising:
a hole between lateral sides of the shelf portion.

3. The stand in accordance with claim 1, wherein the interior backrest portion and the shelf portion each have a proximal attachment end attached to the sheet, and a distal free end.

4. The stand in accordance with claim 1, wherein the sheet is substantially flat in the initial unfolded configuration.

5. The stand in accordance with claim 1, wherein the sheet has opposite front and rear ends; and wherein the stand has a profile with the perimeter base portion, the interior backrest portion and the shelf portion radiating from proximal attachment ends attached to one another at or near the front end, to distal free ends.

6. The stand in accordance with claim 1, further comprising:
indicia indicative of or representing a business, a product, or both, disposed on an outward facing surface of the interior backrest portion, the perimeter base portion, or both.

7. The stand in accordance with claim 1, wherein the sheet comprises and metal; and
further comprising a clear coat disposed on at least an outer surface of the sheet.

8. The stand in accordance with claim 1, wherein:
the first slot has a U-shape and the first fold line comprises a third slot extending between, but spaced-apart from, opposite ends of the first slot and across an opening of the U-shape, the perimeter base portion being defined between the first and third slots, and the perimeter of the sheet;
the second slot has a U-shape and the second fold line comprises a fourth slot extending between, but spaced-apart from, opposite ends of the second slot and across an opening the of the U-shape of the second slot, the interior backrest portion being defined between the second and fourth slots and the perimeter base portion;
the interior backrest portion being movably coupled to the perimeter base portion by a first pair of connectors integral with the sheet and defined between the third slot and the opposite ends of the first slot, the first fold line comprising the first pair of connectors, the first pair of connectors defining living hinges; and
the shelf portion being movably coupled to the interior backrest portion by a second pair of connectors integral with the sheet and defined between the fourth slot and the opposite ends of the second slot, the second fold line comprising the second pair of connectors, the second pair of connectors defining living hinges.

9. A method for providing the stand in accordance with claim 1, comprising:
transporting the sheet in the initial unfolded configuration;
folding the sheet about the first and second fold lines to form the stand;
disposing the stand on the support surface; and
removably disposing a mobile device on the shelf portion of the stand and leaning against the interior backrest portion of the stand.

10. The method in accordance with claim 9, further comprising:
passing a cord through a hole between lateral sides of the shelf portion; and
removably coupling a plug of the cord into a socket of the mobile device.

11. A mobile device stand, comprising:
a) a substantially rigid sheet having both an initial unfolded configuration patterned with slots and fold lines to define a perimeter base, an interior backrest and a shelf, and a subsequent folded configuration with the sheet folded at the fold lines to define the stand;
b) a first slot and a first fold line in the sheet and together surrounding and defining the interior backrest in the sheet and within the perimeter base in the initial unfolded configuration;
c) a second slot and a second fold line in the sheet and together surrounding and defining the shelf in the sheet and within the interior backrest in the initial unfolded configuration; and
d) the interior backrest and the shelf each having a proximal attachment end at the first and second fold lines, respectively, with the proximal attachment ends and the first and second fold lines being proximal one another, and closer to a front of the stand in the subsequent folded configuration than an opposite rear of the stand.

12. The stand in accordance with claim 11, further comprising:
a hole between lateral sides of the shelf.

13. The stand in accordance with claim 11, wherein the sheet is substantially flat in the initial unfolded configuration.

14. The stand in accordance with claim 11, further comprising:
indicia indicative of or representing a business, a product, or both, disposed on an outward facing surface of the interior backrest, the perimeter base, or both.

15. The stand in accordance with claim 11, wherein sheet comprises and metal; and
further comprising a clear coat disposed on at least an outer surface of the sheet.

16. The stand in accordance with claim 11, wherein:
the first slot has a U-shape and the first fold line comprises a third slot extending between, but spaced-apart from, opposite ends of the first slot and across an opening of the U-shape, the perimeter base being defined between the first and third slots, and the perimeter of the sheet;
the second slot has a U-shape and the second fold line comprises a fourth slot extending between, but spaced-apart from, opposite ends of the second slot and across an opening the of the U-shape of the second slot, the interior backrest being defined between the second and fourth slots and the perimeter base portion;
the interior backrest being movably coupled to the perimeter base by a first pair of connectors integral with the sheet and defined between the third slot and the opposite ends of the first slot, the first fold line comprising the first pair of connectors, the first pair of connectors defining living hinges; and
the shelf being movably coupled to the interior backrest by a second pair of connectors integral with the sheet and defined between the fourth slot and the opposite ends of the second slot, the second fold line comprising the second pair of connectors, the second pair of connectors defining living hinges.

17. A method for providing the stand in accordance with claim 11, comprising:
transporting the sheet in the initial unfolded configuration;
folding the sheet about the first and second fold lines to form the stand;
disposing the stand on the support surface; and
removably disposing a mobile device on the shelf of the stand and leaning against the interior backrest of the stand.

18. The method in accordance with claim 17, further comprising:
passing a cord through a hole between lateral sides of the shelf; and
removably coupling a plug of the cord into a socket of the mobile device.

19. A mobile device stand, comprising:
a) a substantially rigid sheet having both an initial unfolded configuration with slots defining portions and fold lines, and a subsequent folded configuration with the sheet folded at the fold lines and the portions being displaced from the flat configuration to define the stand;
b) a perimeter base portion extending around a perimeter of the rigid sheet in the initial unfolded configuration;
c) an interior backrest portion circumscribed by the perimeter base portion in the initial unfolded configuration, and separated from the perimeter base portion by a first slot extending around a majority of the interior backrest portion, and attached to the perimeter base portion by a first fold line;
d) a shelf portion circumscribed by the interior backrest portion in the initial unfolded configuration, and separated from the interior backrest portion by a second slot extending around a majority of the shelf portion, and attached so the interior backrest portion by a second fold line;
e) the interior backrest portion being folded about the first fold line at an acute angle with respect to the perimeter base portion in the subsequent folded configuration;
f) the shelf portion being folded about the second fold line at substantially a right angle with respect to the interior backrest portion in the subsequent folded configuration;
g) the first slot having a U-shape and the first fold line comprising a third slot extending between, but spaced-apart from, opposite ends of the first slot and across an opening of the U-shape, the perimeter base being defined between the first and third slots, and the perimeter of the sheet;
h) the second slot has a U-shape and the second fold line comprises a fourth slot extending between, but spaced-apart from, opposite ends of the second slot and across an opening the of the U-shape of the second slot, the interior backrest being defined between the second and fourth slots and the perimeter base portion;
i) the interior backrest being movably coupled to the perimeter base by a first pair of connectors integral with the sheet and defined between the third slot and the opposite ends of the first slot, the first fold line comprising the first pair of connectors, the first pair of connectors defining living hinges;
j) the shelf being movably coupled to the interior backrest by a second pair of connectors integral with the sheet and defined between the fourth slot and the opposite ends of the second slot, the second fold line comprising the second pair of connectors, the second pair of connectors defining living hinges;
k) a hole between lateral sides of the shelf portion;
l) indicia indicative of or representing a business, a product, or both, disposed on an outward facing surface of the interior backrest portion, the perimeter base portion, or both; and
m) the sheet being substantially flat in the initial unfolded configuration.

20. A method for providing the stand in accordance with claim 19, comprising:
transporting the sheet in the initial unfolded configuration;
folding the sheet about the first and second fold lines to form the stand;
disposing the stand on the support surface;
passing a cord through the hole between the lateral sides of the shelf portion;
removably coupling a plug of the cord into a socket of a mobile device; and
removably disposing the mobile device on the shelf portion of the stand and leaning against the interior backrest portion of the stand.
